(19) United States
(12) Patent Application Publication
(10) Pub. No.: US 2026/0180538 A1
(43) Pub. Date: Jun. 25, 2026

(54) LOW PASS FILTER AND DIPLEXER INCLUDING THE SAME

(71) Applicant: Murata Manufacturing Co., Ltd., Nagaokakyo-shi (JP)

(72) Inventor: Naoki MIZOGUCHI, Nagaokakyo-shi (JP)

(73) Assignee: Murata Manufacturing Co., Ltd., Nagaokakyo-shi (JP)

(21) Appl. No.: 19/387,707

(22) Filed: Nov. 13, 2025

(30) Foreign Application Priority Data
Dec. 20, 2024 (JP) 2024-225177

(51) Int. Cl. H03H 7/01; H03H 7/46

(52) U.S. Cl. CPC H03H 7/0115; H03H 7/46

(57) ABSTRACT

A low pass filter includes a multilayer body including a plurality of dielectric layers in a stacking direction, the multilayer body including an input terminal, an output terminal, and a ground terminal. A first resonator is connected to the input terminal and the resonator RC3 is connected between the first resonator and the output terminal. A capacitor is connected between a connection node between the first and second resonators and the ground terminal. Each resonator is an LC parallel resonant circuit including an inductor formed by a via primary inductor via extending in the stacking direction. An adjustment circuit adjusts coupling between the first and second resonators and includes its own via having a first end connected to the ground terminal. In a plan view from the stacking direction, the via of the adjustment circuit is between of the primary inductors vias of the first and second resonators.

### CROSS-REFERENCE TO RELATED APPLICATION

The present application claims priority to Japanese patent application JP 2024-225177, filed Dec. 20, 2024, the entire contents of which being incorporated herein by reference.

### BACKGROUND

### 1. Field

The present disclosure relates to a low pass filter and a diplexer including the same and, more specifically, to a technique for improving attenuation characteristics in the low pass filter.

### 2. Description of the Related Art

International Publication No. 2018/066339 discloses a five-stage LC filter (band pass filter) including five resonators. In the LC filter, magnetic coupling inductors are connected in parallel with respective inductors of a first-stage resonator on an input terminal side and a fifth-stage resonator on an output terminal side.

In the LC filter disclosed in International Publication No. 2018/066339, desired frequency characteristics are achieved by adjusting coupling between adjacent resonators using each of the magnetic coupling inductors.

### SUMMARY

In general, to increase a Q factor and frequency characteristics in low pass filters, there is a configuration in which a via is used as an inductor of a resonator constituting a filter device. In such a configuration, however, resonators are coupled to each other via a magnetic field and/or an electric field through the via, sufficient isolation between the resonators is unable to be provided, and a specified or higher level of attenuation is unable to be achieved in some cases.

To deal with such issues, it is conceivable that a distance between vias of resonators is increased. In this case, however, the size of the filter device has to be increased, and thus an increase in the distance between vias is not suited to a filter device including multiple resonators to achieve relatively large attenuation, or to a case where miniaturization is demanded.

The present disclosure has been made to deal with such issues and aims to improve attenuation characteristics in a low pass filter without increasing the device size.

A low pass filter according to a present disclosure includes: a multilayer body including a plurality of dielectric layers stacked and laminated in a stacking direction; an input terminal, an output terminal, and a ground terminal that are disposed at the multilayer body; a first resonator; a second resonator; a first capacitor; and a first adjustment circuit. The first resonator is connected to the input terminal. The second resonator is connected between the first resonator and the output terminal. The first capacitor is connected between a connection node between the first resonator and the second resonator and the ground terminal. The first adjustment circuit adjusts coupling between the first resonator and the second resonator. Each of the first resonator and the second resonator is an LC parallel resonant circuit including a capacitor, and an inductor having a via extending in the stacking direction. The first adjustment circuit includes a via having one end connected to the ground terminal. When viewed in a plan view from the stacking direction, the via of the first adjustment circuit is disposed along the via of the first resonator and the via of the second resonator in a region between the via of the first resonator and the via of the second resonator.

In the low pass filter according to the present disclosure, in the first resonator and the second resonator disposed in series in a signal transmission path, in the region between the via of the first resonator and the via of the second resonator, the first adjustment circuit including the via disposed along these vias is provided. The one end of the via of the first adjustment circuit is connected to the ground terminal, and the first adjustment circuit is capable of adjusting (reducing) coupling between the first resonator and the second resonator. As a result, isolation between the resonators can be provided, thus enabling improved attenuation characteristics in the low pass filter without increasing the device size.

### BRIEF DESCRIPTION OF THE DRAWINGS

FIG. 1 is a block diagram of a communication device including a diplexer in which a low pass filter according to an embodiment is used;

FIG. 2 is an equivalent circuit diagram of the low pass filter according to the embodiment;

FIG. 3 includes diagrams illustrating a principle by which attenuation characteristics are improved by a coupling adjustment circuit;

FIG. 4 is a graph illustrating bandpass characteristics exhibited after adjustment for return loss in an example in FIG. 3;

FIG. 5 is an external view of the low pass filter according to the embodiment;

FIG. 6 is an exploded perspective view illustrating an example of a detailed structure of the low pass filter according to the embodiment;

FIG. 7 is a plan view illustrating the disposition of a coupling adjustment circuit in a low pass filter in Modification 1;

FIG. 8 includes diagrams illustrating changes in bandpass characteristics based on configurations of coupling adjustment circuits;

FIG. 9 includes diagrams illustrating a configuration and bandpass characteristics of a low pass filter in Modification 2; and

FIG. 10 is an equivalent circuit diagram of a low pass filter according to Modification 3.

### DESCRIPTION OF EMBODIMENTS

An embodiment of the present disclosure will be described in detail below with reference to the drawings. Note that identical or corresponding elements or portions in the drawings are denoted by the same reference signs and a repeated description thereof is not given.

### Basic Configuration of Communication Device

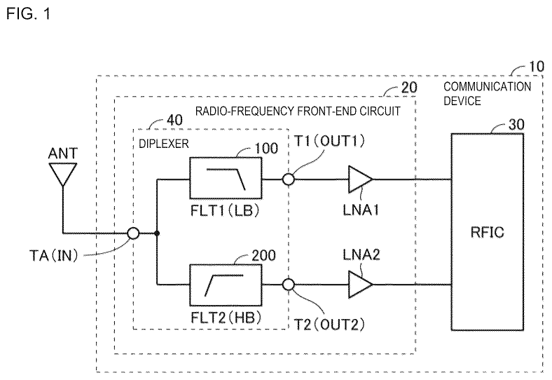

FIG. 1 is a block diagram of a radio-frequency front-end circuit 20 including a diplexer 40 in which a low pass filter 100 according to the embodiment is used, and a communication device 10 including the radio-frequency front-end circuit 20. The radio-frequency front-end circuit 20 separates radio-frequency signals received by an antenna device ANT into a plurality of predetermined frequency bands and transmits them to a subsequent processing circuit. The radio-frequency front-end circuit 20 is used in a communication device, for example, a mobile terminal, such as a mobile phone, smart phone, or tablet, or a personal computer having a communication function.

Referring to FIG. 1, the communication device 10 includes the radio-frequency front-end circuit 20 including the diplexer 40, and an RF signal processing circuit (hereinafter, also referred to as “RFIC”) 30. The radio-frequency front-end circuit 20 illustrated in FIG. 1 is a reception front-end circuit. The radio-frequency front-end circuit 20 includes the diplexer 40, and amplifier circuits LNA1 and LNA2.

The diplexer 40 includes a filter 100 (FLT1) and a filter 200 (FLT2) whose pass bands are frequency ranges different from each other.

The filter 100 is connected between an antenna terminal TA, which is a common terminal, and a terminal T1. The filter 100 is a low pass filter whose pass band is a frequency range of a low band (LB) group and whose non-pass band is a frequency range of a high band (HB) group. The filter 200 is connected between the antenna terminal TA and a terminal T2. The filter 200 is a high pass filter whose pass band is the frequency range of the high band group and whose non-pass band is the frequency range of the low band group. Note that, in the following description, the filter 100 may be referred to as “low pass filter 100” and the filter 200 may be referred to as “high pass filter 200” in some cases.

Each of the filters 100 and 200 passes, of radio-frequency signals received by the antenna device ANT, a radio-frequency signal corresponding to the pass band of the filter. Thus, the signals received from the antenna device ANT are separated into signals in a plurality of predetermined frequency bands.

Each of the amplifier circuits LNA1 and LNA2 is a so-called low noise amplifier. The amplifier circuits LNA1 and LNA2 amplify radio-frequency signals that have passed through the corresponding filters with low noise and transmit the signals to the RFIC 30.

The RFIC 30 is an RF signal processing circuit that processes radio-frequency signals transmitted and received by the antenna device ANT. Specifically, the RFIC 30 performs signal processing, such as down-conversion, on a radio-frequency signal input from the antenna device ANT through a reception signal path of the radio-frequency front-end circuit 20 and outputs a reception signal generated through the signal processing to a baseband signal processing circuit (not illustrated).

When the radio-frequency front-end circuit 20 is used as a reception circuit as illustrated in FIG. 1, in the diplexer 40, the antenna terminal TA serves as an input terminal IN, and the terminal T1 and the terminal T2 respectively serve as a first output terminal OUT1 and a second output terminal OUT2. On the other hand, the radio-frequency front-end circuit can also be used as a transmission circuit. In this case, each of the terminal T1 and the terminal T2 of the diplexer 40 serves as an input terminal, and the antenna terminal TA serves as a common output terminal. In that case, as an amplifier included in each amplifier circuit, a power amplifier is used in place of the low noise amplifier.

### Configuration of Diplexer

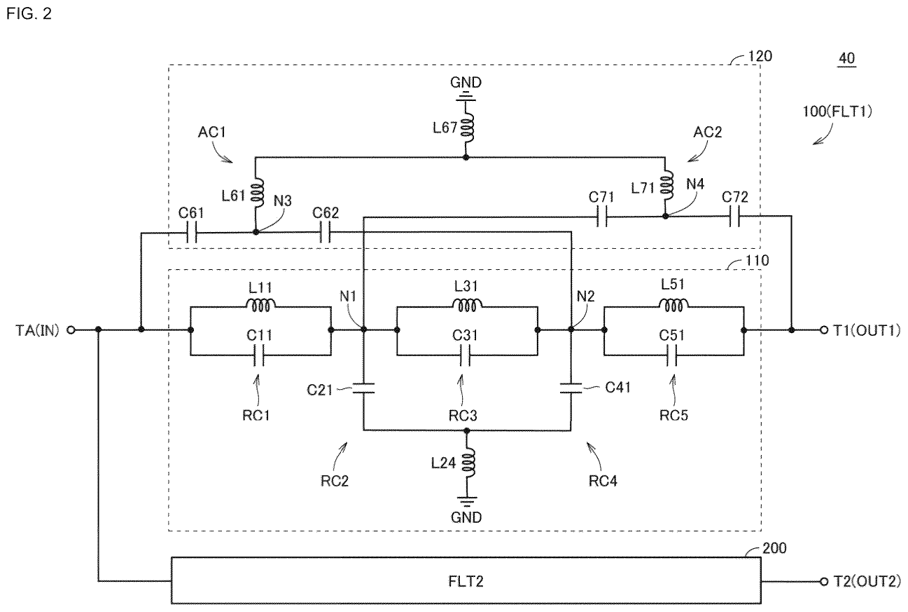

FIG. 2 is a diagram illustrating an example of an equivalent circuit of the diplexer 40 in FIG. 1. As illustrated in FIG. 1, the low pass filter 100 is connected between the antenna terminal TA and the terminal T1. Additionally, the high pass filter 200 is connected between the antenna terminal TA and the terminal T2.

As described below, in the present disclosure, bandpass characteristics of the low pass filter 100 in the diplexer 40 is intended to be improved. For this reason, in FIG. 2, only an equivalent circuit of the low pass filter 100 is illustrated, and an equivalent circuit of the high pass filter 200 is omitted.

Referring to FIG. 2, the low pass filter 100 includes a filter circuit 110 and a coupling adjustment circuit 120.

The filter circuit 110 is a signal transmission path through which a radio-frequency signal input from the antenna terminal TA actually passes. The filter circuit 110 includes three resonators RC1, RC3, and RC5 disposed in series between the antenna terminal TA and the terminal T1, and two resonators RC2 and RC4 disposed between connection nodes between the resonators and a ground terminal GND. That is, the filter circuit 110 is a so-called fifth-order low pass filter.

Each of the resonators RC1, RC3, and RC5 is an LC parallel resonator in which an inductor and a capacitor are connected in parallel. The resonator RC1 includes an inductor L11 and a capacitor C11. The resonator RC3 includes an inductor L31 and a capacitor C31. The resonator RC5 includes an inductor L51 and a capacitor C51. Each inductor is formed by one or more conductive vias extending in the stacking direction. The main current-carrying via that constitutes the primary inductance for each LC parallel resonant circuit is referred to herein as a “primary inductor via.”

One end of the inductor L11 is connected to the antenna terminal TA. One end of the inductor L51 is connected to the terminal T1. The inductor L31 is connected between the other end of the inductor L11 and the other end of the inductor L51. That is, the inductors L11, L31, and L51 are connected in series in this order between the antenna terminal TA and the terminal T1.

The capacitor C11 is connected in parallel with the inductor L11. The capacitor C31 is connected in parallel with the inductor L31. The capacitor C51 is connected in parallel with the inductor L51.

Each of the resonators RC2 and RC4 is an LC series resonator in which an inductor and a capacitor are connected in series. The resonator RC2 includes a capacitor C21 and an inductor L24. The resonator RC4 includes a capacitor C41 and the inductor L24. Note that the inductor L24 is shared by the resonator RC2 and the resonator RC4.

One end of the capacitor C21 of the resonator RC2 is connected to a connection node N1 between the resonator RC1 and the resonator RC3. The other end of the capacitor C21 is connected to the ground terminal GND via the inductor L24.

One end of the capacitor C41 of the resonator RC4 is connected to a connection node N2 between the resonator RC3 and the resonator RC5. The other end of the capacitor C41 is connected to the ground terminal GND via the inductor L24.

In the filter circuit 110, a signal in a frequency band lower than a cutoff frequency determined by the resonant frequencies of the resonators RC1, RC3, and RC5 passes from the antenna terminal TA to the terminal T1. On the other hand, a signal in a frequency band higher than the cutoff frequency is transmitted to a ground through the resonator RC2 and/or the resonator RC4.

The coupling adjustment circuit 120 is a circuit for adjusting a state of coupling between the resonator RC1 and the resonator RC3, and a state of coupling between the resonator RC3 and the resonator RC5. The coupling adjustment circuit 120 includes an adjustment circuit AC1 for adjusting the state of coupling between the resonator RC1 and the resonator RC3, and an adjustment circuit AC2 for adjusting the state of coupling between the resonator RC3 and the resonator RC5.

The adjustment circuit AC1 includes inductors L61 and L67, and capacitors C61 and C62. The adjustment circuit AC2 includes inductors L71 and 67, and capacitors C71 and C72. Note that the inductor L67 is shared by the adjustment circuit AC1 and the adjustment circuit AC2.

In the adjustment circuit AC1, the capacitors C61 and C62 are connected in series between the antenna terminal TA and the connection node N2. One end of the inductor L61 is connected to a connection node N3 between the capacitor C61 and the capacitor C62. The other end of the inductor L61 is connected to the ground terminal GND via the inductor L67.

In the adjustment circuit AC2, the capacitors C71 and C72 are connected in series between the terminal T1 and the connection node N1. One end of the inductor L71 is connected to a connection node N4 between the capacitor C71 and the capacitor C72. The other end of the inductor L71 is connected to the ground terminal GND via the inductor L67.

Note that the capacitors C61 and C62 of the adjustment circuit AC1 in an actual configuration are stray capacitances occurring between vias constituting the respective inductors L11 and L31 in the resonators RC1 and RC3 and a via constituting the inductor L61 in the adjustment circuit AC1.

Similarly, the capacitors C71 and C72 of the adjustment circuit AC2 in an actual configuration are stray capacitances occurring between vias constituting the respective inductors L31 and L51 in the resonators RC3 and RC5 and a via constituting the inductor L71 in the adjustment circuit AC2.

### Effects of Coupling Adjustment Circuit

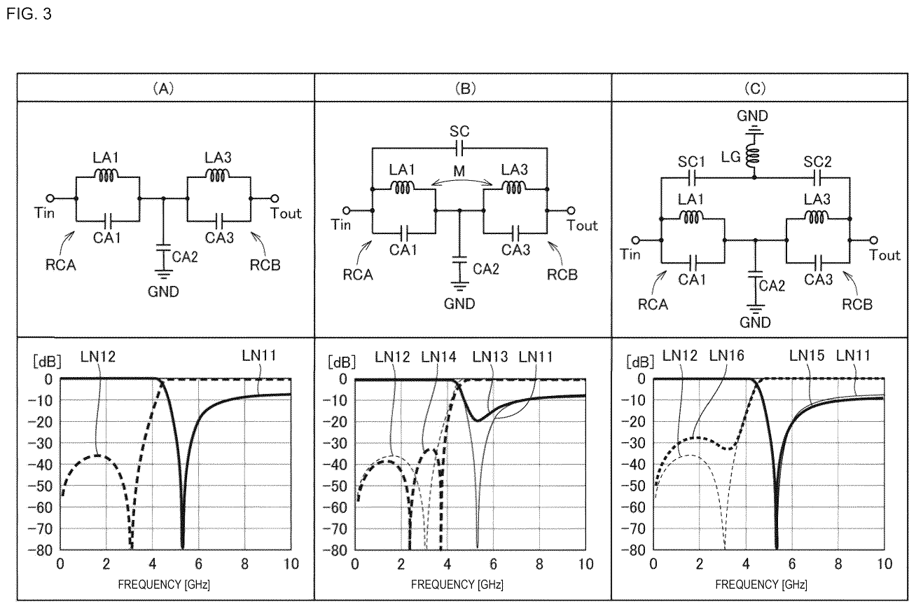

A principle by which attenuation characteristics of the low pass filter can be improved by using such a coupling adjustment circuit will be described with reference to FIG. 3. Note that FIG. 3 illustrates, as an example, a third-order low pass filter for ease of explanation. In the filter circuit 110 in FIG. 2, there are two sets of constituents, that is, a set of the resonators RC1, RC2, and RC3 and a set of the resonators RC3, RC4, and RC5 each correspond to the third-order low pass filter.

In FIG. 3, a left diagram (A) illustrates a configuration of an ideal third-order low pass filter, a middle diagram (B) illustrates a configuration of an actual low pass filter, and a right diagram (C) illustrates a configuration of a low pass filter according to the embodiment. An upper section illustrates a schematic circuit, and a lower section illustrates a graph of simulation of bandpass characteristics of the circuit.

In graphs, solid lines (LN11, LN13, LN15) represent insertion loss, and dashed lines (LN12, LN14, LN16) represent return loss. Furthermore, in the middle diagram (B) and the right diagram (C), a graph in the left diagram (A) is illustrated in thin lines for comparison.

The low pass filter in the left diagram (A) is an ideal (theoretical) low pass filter having almost the same configuration as the filter circuit 110 illustrated in FIG. 2. This low pass filter includes a resonator RCA connected to an input terminal Tin, a resonator RCB connected to an output terminal Tout, and a capacitor CA3 connected between a connection node NA between the resonator RCA and the resonator RCB and a ground terminal GND. The resonator RCA includes an inductor LA1 and a capacitor CA1 that are connected in parallel between the input terminal Tin and the connection node NA. The resonator RCB includes an inductor LA2 and a capacitor CA2 that are connected in parallel between the connection node NA and the output terminal Tout.

In this low pass filter, as represented by the line LN11 in the lower graph, an attenuation pole is generated at around 5.2 GHz in the non-pass band, and relatively steep attenuation characteristics can be achieved, thus enabling desired attenuation to be achieved.

However, when a circuit is provided within a multilayer body of dielectrics, a sufficient distance between resonators is unable to be provided due to device size constraints, and thus no small amount of capacitive coupling occurs between adjacent resonators due to a stray capacitance SC as illustrated in the middle diagram (B). Furthermore, inductive coupling M can occur between the inductor LA1 and the inductor LA3.

In the case in the middle diagram (B), in a signal transmission path from the input terminal Tin to the output terminal Tout, paths through the stray capacitance SC and the inductive coupling M occur in addition to a path through the resonators RCA and RCB connected in series. Of input radio-frequency signals, a signal on a relatively high frequency side is transmitted to the output terminal Tout via these added paths, attenuation at the attenuation pole decreases as represented by the solid line LN13, and attenuation characteristics in the non-pass band can deteriorate.

In the low pass filter in the right diagram (C) corresponding to the embodiment, a shunt-connected inductor LG (corresponding to the inductors L61, L71, and L67 illustrated in FIG. 2) is disposed to generate the stray capacitance SC occurring between the resonators as stray capacitances SC1 and SC2 between the resonators and the inductor LG, and these stray capacitances SC1 and SC2 are connected to the ground terminal GND. That is, a shunt-connected high pass filter is substantially formed by the stray capacitances SC1 and SC2 and the inductor LG.

In such a configuration, a radio-frequency signal that flows into a path formed by the stray capacitances SC1 and SC2 is transmitted to the ground through the inductor LG and is no longer transmitted to the terminal T1. At this time, part of the inductor LG is disposed between the inductor LA1 and the inductor LA3, and thus the inductive coupling M occurring between the inductor LA1 and the inductor LA3 includes inductive coupling between the inductor LA1 and the inductor LG and inductive coupling between the inductor LA3 and the inductor LG. This reduces the amount of inductive coupling occurring between the inductor LA1 and the inductor LA3 compared with that in the circuit illustrated in the middle diagram (B), thereby also producing the effect of reducing deterioration of isolation between the resonators. As a result, even when a stray capacitance and inductive coupling occur between the resonators, as represented by the solid line LN15, the attenuation characteristics in the non-pass band can be improved to a level equivalent to those in the left diagram (A).

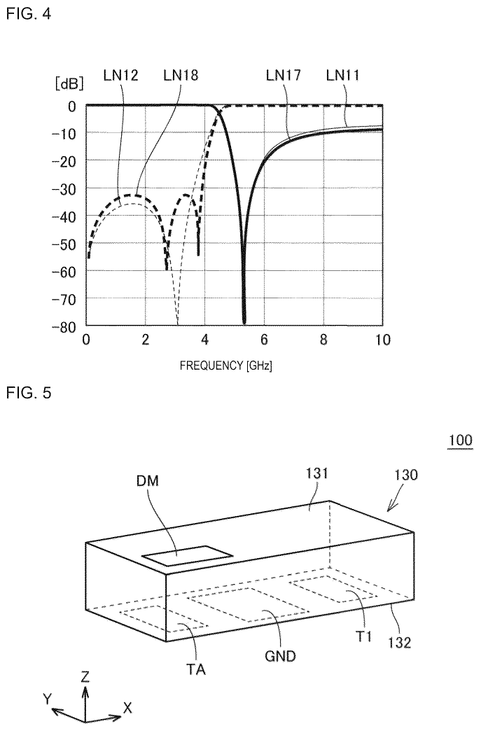

Note that, in the low pass filter in the right diagram (C), the return loss is worse than that in the left diagram (A). However, this can be improved by adjusting the capacitance of the capacitor CA2. In FIG. 4, insertion loss and return loss exhibited after adjusting the capacitor CA2 are respectively represented by a solid line KN17 and a dashed line LN18. As illustrated in FIG. 4, when the capacitance of the capacitor CA2 is adjusted, the return loss in a 0- to 4-GHz range in the pass band can be improved to the same level as that in the left diagram (A) in FIG. 3.

As described above, in the filter circuit 110 in FIG. 2, a third-order low pass filter, such as that illustrated in FIG. 3, is constituted by the resonators RC1, RC2, and RC3, and is also constituted by the resonators RC3, RC4, and RC5. Thus, in the filter circuit 110 as well, deterioration of attenuation characteristics due to a stray capacitance and inductive coupling that inevitably occur between resonators from device size constraints can be reduced.

### Detailed Configuration of Low Pass Filter

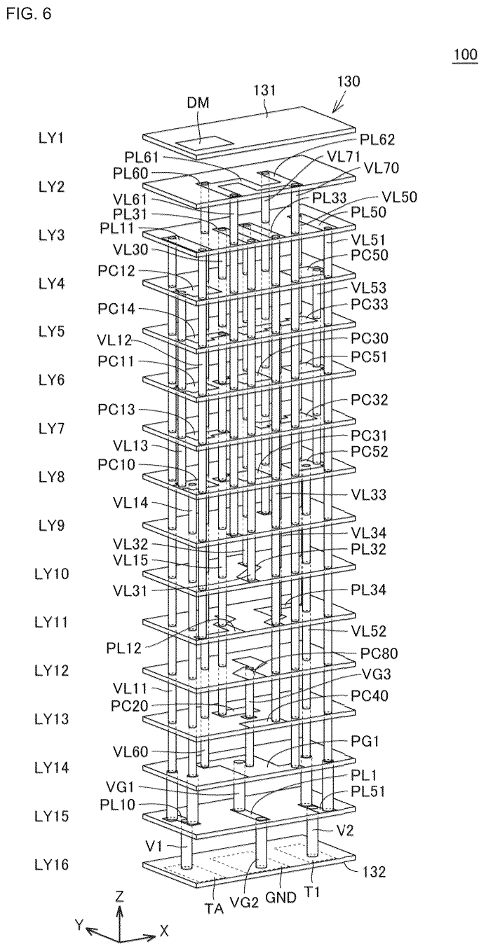

Next, a detailed configuration of the low pass filter 100 according to the embodiment will be described with reference to FIGS. 5 and 6. Note that FIGS. 5 and 6 illustrate, for ease of understanding, an example where the low pass filter 100 is a discrete device disposed singly within a multilayer body of dielectrics. However, the low pass filter 100 may be disposed as a portion of the diplexer 40 within a single multilayer body together with the high pass filter 200.

Referring to FIGS. 5 and 6, the low pass filter 100 includes a rectangular parallelepiped- or substantially rectangular parallelepiped-shaped multilayer body 130 formed by stacking a plurality of dielectric layers LY1 to LY16 along a predetermined direction. In the multilayer body 130, a direction in which the plurality of dielectric layers LY1 to LY16 are stacked is defined as a stacking direction. Each dielectric layer of the multilayer body 130 is made of ceramic, such as Low Temperature Co-fired Ceramics (LTCC), or resin.

Within the multilayer body 130, a plurality of electrodes provided at the dielectric layers and a plurality of vias provided between the dielectric layers constitute inductors and capacitors that constitute the low pass filter 100. Note that, in the following description, an example will be described where the multilayer body 130 has a multilayer structure as described above for ease of explanation. However, the multilayer body 130 may also have a single-layer structure.

In the present specification, “via” refers to a conductor formed within dielectric layers to connect electrodes provided at different dielectric layers. A via is made, for example, of a conductive paste, plating, and/or a metal pin. Furthermore, in the following description, the stacking direction of the dielectric layers LY1 to LY16 in the multilayer body 130 is defined as “Z-axis direction”, a direction perpendicular to the Z-axis direction and along the long side of the multilayer body 130 is defined as “X-axis direction”, and a direction along the short side of the multilayer body 130 is defined as “Y-axis direction”. Additionally, in the following, a positive direction and a negative direction of a Z axis in figures may be respectively referred to as upper and lower.

The multilayer body 130 includes an upper surface 131 (first main surface) and a lower surface 132 (second main surface). A directional mark DM for identifying the orientation of the low pass filter 100 is disposed at the upper surface 131 (dielectric layer LY1) of the multilayer body 130. As illustrated in FIG. 5, as external terminals for connecting the low pass filter 100 to external devices, the antenna terminal TA, the terminal T1, and the ground terminal GND are disposed at the lower surface 132 (dielectric layer LY16) of the multilayer body 130. The external terminals are flat-plate-shaped electrodes and are Land Grid Array (LGA) terminals regularly disposed at the lower surface 132 of the multilayer body 130.

The antenna terminal TA disposed at the dielectric layer LY16, which is the lower surface 132, is connected to a flat-plate electrode PL10 disposed at the dielectric layer LY15 through a via V1. The flat-plate electrode PL10 is an electrode in the form of a substantially L-shaped strip and has an end portion in a positive direction of a Y axis to which a via VL11 is connected and an end portion in a negative direction of the Y axis to which a via VL14 is connected.

The via VL11 is connected to a flat-plate electrode PL11 disposed at the dielectric layer LY3. The flat-plate electrode PL11 is a linear electrode extending along the Y axis and has an end portion in the positive direction of the Y axis to which the via VL11 is connected. The flat-plate electrode PL11 has an end portion in the negative direction of the Y axis at which a via VL12 is disposed and is connected to one end of a strip-shaped flat-plate electrode PL12 disposed at the dielectric layer LY11 by the via VL12.

The via VL14 connected to the flat-plate electrode PL10 is connected to a capacitor electrode PC10 disposed at the dielectric layer LY8. Furthermore, the capacitor electrode PC10 is connected by a via VL13 to a capacitor electrode PC11 disposed at the dielectric layer LY6 and also to a capacitor electrode PC12 disposed at the dielectric layer LY4.

All of the capacitor electrodes PC10, PC11, and PC12 are substantially rectangular flat-plate electrodes. When viewed in a plan view from the stacking direction, each of the capacitor electrodes PC10 and PC11 at least partially overlaps a capacitor electrode PC13 disposed at the dielectric layer LY7. Furthermore, when viewed in a plan view from the stacking direction, each of the capacitor electrodes PC11 and PC12 at least partially overlaps a capacitor electrode PC14 disposed at the dielectric layer LY5.

The capacitor electrodes PC13 and PC14 are rectangular flat-plate electrodes with a portion projecting in the X-axis direction, and a via VL15 is connected to this projecting portion. The via VL15 is connected to a middle portion of the flat-plate electrode PL12 at the dielectric layer LY11. Furthermore, the via VL15 is also connected to a capacitor electrode PC30 disposed at the dielectric layer LY6 and a capacitor electrode PC31 disposed at the dielectric layer LY8.

The capacitor electrodes PC10 to PC14 constitute the capacitor C11 illustrated in FIG. 2. Furthermore, the flat-plate electrodes PL10 and PL11 and vias VL11 to VL14 constitute the inductor L11 illustrated in FIG. 2. That is, the capacitor electrodes PC10 to PC14, the flat-plate electrodes PL10 and PL11, and the vias VL11 to VL14 constitute the resonator RC1.

A via VL30 is connected to the other end of the flat-plate electrode PL12 at the dielectric layer LY11. The via VL30 is connected to a capacitor electrode PC20 disposed at the dielectric layer LY13 and is also connected to a flat-plate electrode PL31 disposed at the dielectric layer LY3.

Like the flat-plate electrode PL11, the flat-plate electrode PL31 is a linear electrode extending along the Y axis and has an end portion in the positive direction of the Y axis to which the via VL30 is connected. An end portion of the flat-plate electrode PL31 in the negative direction of the Y axis is connected to one end of a strip-shaped flat-plate electrode PL32 disposed at the dielectric layer LY10 through a via VL31.

A via VL32 is connected to the other end of the flat-plate electrode PL32. The via VL32 is connected to a flat-plate electrode PL33 disposed at the dielectric layer LY3. The flat-plate electrode PL33 is a linear electrode disposed in parallel to the flat-plate electrode PL31 and has an end portion in the positive direction of the Y axis to which the via VL32 is connected. An end portion of the flat-plate electrode PL31 in the negative direction of the Y axis is connected through a via VL33 to one end of a strip-shaped flat-plate electrode PL34 disposed at the dielectric layer LY11 and also to a capacitor electrode PC40 disposed at the dielectric layer LY13.

A via VL34, which is hidden behind the via VL33 and is hard to see in FIG. 6, is connected to a middle portion of the flat-plate electrode PL34. The flat-plate electrode PL34 is connected by the via VL34 to a capacitor electrode PC32 disposed at the dielectric layer LY7 and to a capacitor electrode PC33 disposed at the dielectric layer LY5.

All of the capacitor electrodes PC30 to PC33 are substantially rectangular flat-plate electrodes and at least partially overlap one another when viewed in a plan view from the stacking direction. The capacitor electrodes PC30 to PC33 constitute the capacitor C31 illustrated in FIG. 2. Furthermore, the flat-plate electrodes PL31 to PL33 and the vias VL30 to VL33 constitute the inductor L31 illustrated in FIG. 2. That is, the capacitor electrodes PC30 to PC33, the flat-plate electrodes PL31 to PL33, and the vias VL15, and VL30 to VL34 constitute the resonator RC3.

A via VL50, which is hidden behind a via VL70 and is hard to see in FIG. 6, is connected to the other end of the flat-plate electrode PL34. The via VL50 is connected to a flat-plate electrode PL50 disposed at the dielectric layer LY3.

The flat-plate electrode PL50 is a linear electrode extending along the Y axis and has an end portion in the positive direction of the Y axis to which the via VL50 is connected. The flat-plate electrode PL50 has an end portion in the negative direction of the Y axis at which a via VL51 is disposed and is connected to one end of a flat-plate electrode PL51 disposed at the dielectric layer LY15 by the via VL51.

The flat-plate electrode PL51 is an electrode in the form of a substantially L-shaped strip and has an end portion in the negative direction of the Y axis to which the via VL51 is connected and an end portion in the positive direction of the Y axis to which a via VL52 is connected. Furthermore, the flat-plate electrode PL51 is connected to the terminal T1 disposed at the dielectric layer LY16 by a via V2.

The via VL52 is connected to a capacitor electrode PC52 disposed at the dielectric layer LY8. Furthermore, the capacitor electrode PC52 is also connected by a via VL53 to a capacitor electrode PC51 disposed at the dielectric layer LY6 and to a capacitor electrode PC50 disposed at the dielectric layer LY4.

All of the capacitor electrodes PC50, PC51, and PC52 are substantially rectangular flat-plate electrodes. When viewed in a plan view from the stacking direction, each of the capacitor electrodes PC50 and PC51 at least partially overlaps the capacitor electrode PC33 disposed at the dielectric layer LY5. Furthermore, when viewed in a plan view from the stacking direction, each of the capacitor electrodes PC51 and PC52 at least partially overlaps the capacitor electrode PC32 disposed at the dielectric layer LY5.

The capacitor electrodes PC50 to PC52 constitute the capacitor C51 illustrated in FIG. 2. Furthermore, the flat-plate electrodes PL50 and PL51 and the vias VL50 to VL53 constitute the inductor L51 illustrated in FIG. 2. That is, the capacitor electrodes PC50 to PC52, the flat-plate electrodes PL50 and PL51, and the vias VL50 to VL53 constitute the resonator RC5.

Each of the capacitor electrodes PC20 and PC40 disposed at the dielectric layer LY13 is a substantially rectangular flat-plate electrode extending in the X-axis direction. When viewed in a plan view from the stacking direction, the capacitor electrodes PC20 and PC40 overlap a capacitor electrode PG1 disposed at the dielectric layer LY14. Furthermore, when viewed in a plan view from the stacking direction, at least a portion of each of the capacitor electrodes PC20 and PC40 also overlaps a capacitor electrode PC80 disposed at the dielectric layer LY12.

The capacitor electrode PC80 is connected to the capacitor electrode PG1 at the dielectric layer LY14 by a via VG3. The capacitor electrode PG1 is connected to the ground terminal GND disposed at the dielectric layer LY16 by a via VG1, a flat-plate electrode PL1 disposed at the dielectric layer LY15, and a via VG2.

The capacitor electrode PC20 and the capacitor electrodes PG1 and PC80 constitute the capacitor C21 illustrated in FIG. 2. Furthermore, the capacitor electrode PC40 and the capacitor electrodes PG1 and PC80 constitute the capacitor C41 illustrated in FIG. 2. Additionally, the vias VG1 and VG2 and the flat-plate electrode PL1 constitute the inductor L24 illustrated in FIG. 2.

That is, the capacitor electrodes PC20, PG1, and PC80, the vias VG1 and VG2, and the flat-plate electrode PL1 constitute the resonator RC2 illustrated in FIG. 2. Similarly, the capacitor electrodes PC40, PG1, and PC80, the vias VG1 and VG2, and the flat-plate electrode PL1 constitute the resonator RC4 illustrated in FIG. 2.

Vias VL60 and VL70 are further connected to the capacitor electrode PG1. The via VL60 is connected to a flat-plate electrode PL60 disposed at the dielectric layer LY2. The flat-plate electrode PL60 is a linear electrode extending along the Y axis and has an end portion in the positive direction of the Y axis to which the via VL60 is connected. A via VL61 is connected to an end portion of the flat-plate electrode PL60 in the negative direction of the Y-axis. The other end of the via VL61 extends up to the dielectric layer LY9, and an end portion thereof is an open end.

The flat-plate electrode PL60 and the via VL60 constitute the inductor L61 illustrated in FIG. 2. Furthermore, the vias VG1 and VG2 and the flat-plate electrode PL1, which constitute the above-described inductor L24, also function as the inductor L67 illustrated in FIG. 2.

When viewed in a plan view from the stacking direction, the via VL60 is disposed along the via VL11 in the resonator RC1 and the via VL30 in the resonator RC3 in a region between the via VL11 and the via VL30. Thus, the via VL60 and the via VL11 are capacitively coupled by a stray capacitance, and the via VL60 and the via VL30 are capacitively coupled by a stray capacitance.

Hence, the capacitor C61 illustrated in FIG. 2 is formed by capacitive coupling between the via VL60 and the via VL11. Similarly, the capacitor C62 illustrated in FIG. 2 is formed by capacitive coupling between the via VL60 and the via VL30. That is, the vias VL60, VG1, and VG2 and the flat-plate electrodes PL1 and PL60 constitute the adjustment circuit AC1 illustrated in FIG. 2.

Note that the via VL61 functions as a stub (open stub) for adjusting the frequency of an attenuation pole generated by coupling between the resonator RC1 and the resonator RC3. For this reason, there can be a case where the via VL61 is not provided, depending on the frequency of an attenuation pole to be generated. Furthermore, the other end of the via VL61 may be connected to the ground terminal GND to serve as a short stub.

The via VL70 is connected to a flat-plate electrode PL62 disposed at the dielectric layer LY3. The flat-plate electrode PL62 is a linear electrode extending along the Y axis and has an end portion in the negative direction of the Y axis to which the via VL70 is connected. A via VL71 is connected to an end portion of the flat-plate electrode PL62 in the positive direction of the Y axis. The other end of the via VL71 extends up to the dielectric layer LY9, and an end portion thereof is an open end. Furthermore, at the dielectric layer LY2, the flat-plate electrode PL62 is connected to the flat-plate electrode PL60 by a flat-plate electrode PL61. Note that, like the via VL61, the via VL71 functions as a stub for adjusting the frequency of an attenuation pole generated by coupling between the resonator RC3 and the resonator RC5.

The flat-plate electrode PL62 and the via VL70 constitute the inductor L71 illustrated in FIG. 2. Furthermore, as described above, the vias VG1 and VG2 and the flat-plate electrode PL1 also function as the inductor L67 illustrated in FIG. 2.

When viewed in a plan view from the stacking direction, the via VL70 is disposed along the via VL30 in the resonator RC3 and the via VL50 in the resonator RC5 in a region between the via VL30 and the via VL50. Thus, the via VL70 and the via VL30 are capacitively coupled by a stray capacitance, and the via VL70 and the via VL50 are capacitively coupled by a stray capacitance.

Hence, the capacitor C71 in FIG. 2 is formed by capacitive coupling between the via VL70 and the via VL30. Similarly, the capacitor C72 in FIG. 2 is formed by capacitive coupling between the via VL70 and the via VL50. That is, the vias VL70, VG1, and VG2 and the flat-plate electrodes PL1 and PL62 constitute the adjustment circuit AC2 illustrated in FIG. 2.

As described above, electrodes and vias are disposed in the multilayer body 130, thereby providing the low pass filter 100 illustrated in FIG. 2. When viewed in a plan view from the stacking direction, the via VL60 of the first adjustment circuit AC1 is between the primary inductor via VL11 of the first resonator RC1 and the primary inductor via VL30 of the second resonator RC3.

### Modification 1

In the above-described description, although the flat-plate electrode PL60 included in the adjustment circuit AC1 and the flat-plate electrode PL62 included in the adjustment circuit AC2 are connected by the flat-plate electrode PL61 at the dielectric layer LY2, the flat-plate electrode PL61 does not necessarily have to be provided.

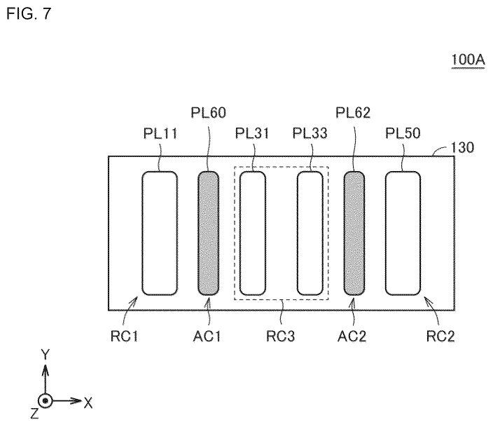

FIG. 7 is a plan view of the dielectric layers LY2 and LY3 in a low pass filter 100A in Modification 1, as viewed from the stacking direction. As illustrated in FIG. 7, in the low pass filter 100A in Modification 1, the flat-plate electrode PL62 at the dielectric layer LY2 is not disposed.

Even in a configuration, such as that in Modification 1, the adjustment circuit AC1 including the flat-plate electrode PL60 and the adjustment circuit AC2 including the flat-plate electrode PL62 are provided, thus enabling improved attenuation characteristics in the non-pass band. As in the embodiment, when magnetic coupling between the adjustment circuit AC1 and the adjustment circuit AC2 is strengthened by directly connecting the adjustment circuit AC1 and the adjustment circuit AC2 using the flat-plate electrode PL61, magnetic field coupling between the inductor L11 and the inductor L51 can be adjusted, and thus attenuation in the vicinity of the pass band of the low pass filter 100 can be adjusted. This can improve attenuation characteristics even further compared with those in Modification 1. In particular, the connection electrode PL61 strengthens the magnetic coupling between the adjustment circuits, which allows for adjustment of the magnetic field coupling between the non-adjacent inductors L11 and L51. This provides an additional mechanism to shape the filter's response.

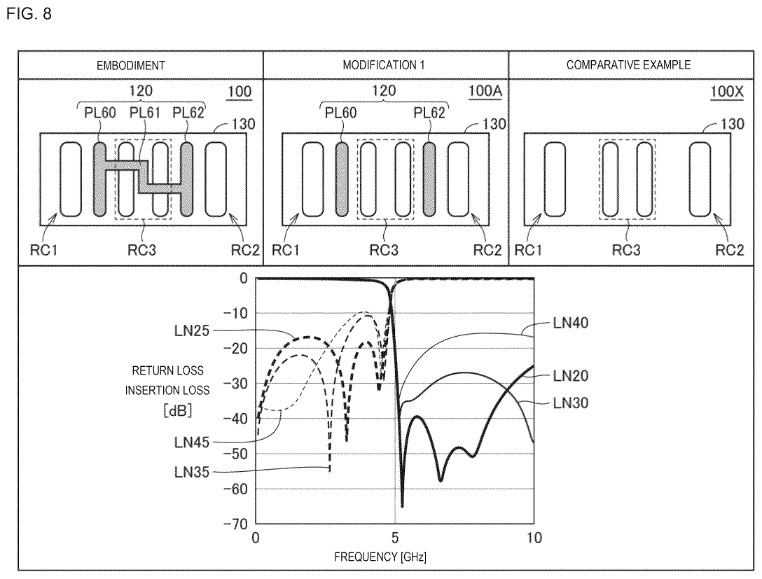

FIG. 8 includes diagrams illustrating bandpass characteristics in the low pass filter 100 according to the embodiment, the low pass filter 100A in Modification 1, and a low pass filter 100X in a comparative example in which no coupling adjustment circuit 120 is provided. An upper section in FIG. 8 illustrates a schematic configuration of the coupling adjustment circuit in each low pass filter, and a lower section illustrates a graph of bandpass characteristics (return loss, insertion loss) in each low pass filter.

In the low pass filter 100X in the comparative example, the adjustment circuits AC1 and AC2 are not provided between the resonator RC1 and the resonator RC3 and between the resonator RC3 and the resonator RC5.

In the lower graph in FIG. 8, solid lines LN20, LN30, and LN40 represent insertion loss, and dashed lines LN25, LN35, and LN45 represent return loss. Furthermore, the lines LN20 and LN25 represent a case of the low pass filter 100 according to the embodiment, and the lines LN30 and LN35 represent a case of the low pass filter 100A in Modification 1. The lines LN40 and LN45 represent a case of the low pass filter 100X in the comparative example.

As illustrated in the graph in FIG. 8, even in Modification 1, attenuation characteristics in the non-pass band are improved compared with those in the comparative example, but attenuation at an attenuation pole in the vicinity of the pass band is about 40 dB. On the other hand, in the low pass filter 100 according to the embodiment, attenuation of about 65 dB is achieved at an attenuation pole in the vicinity of the pass band. In a 5- to 9-GHz region in the non-pass band as well, even more attenuation is provided than those in the comparative example and Modification 1.

As described above, even in the low pass filter 100A in Modification 1, in which no flat-plate electrode PL62 connecting the adjustment circuit AC1 and the adjustment circuit AC2 is included, the attenuation characteristics in the non-pass band can be improved compared with those in the case where no coupling adjustment circuit 120 is provided. Furthermore, the attenuation characteristics can be further improved by connecting the adjustment circuit AC1 and the adjustment circuit AC2 via the flat-plate electrode PL62 as in the low pass filter 100 according to the embodiment.

In the embodiment, “resonator RC1”, “resonator RC3”, and “resonator RC5” respectively correspond to “first resonator”, “second resonator”, and “third resonator” in the present disclosure. In the embodiment, “capacitor C21” and “capacitor C41” respectively correspond to “first capacitor” and “second capacitor” in the present disclosure. In the embodiment, “adjustment circuit AC1” and “adjustment circuit AC2” respectively correspond to “first adjustment circuit” and “second adjustment circuit” in the present disclosure. In the embodiment, “flat-plate electrode PL61” corresponds to “connection electrode” in the present disclosure. In the embodiment, “inductor L24” corresponds to “ground inductor” in the present disclosure. In the embodiment, “antenna terminal TA” corresponds to “input terminal” in the present disclosure.

### Modification 2

In Modification 2, a case will be described in which features in the present disclosure are applied to a third-order low pass filter. Furthermore, in Modification 2, first-order and third-order resonators connected in series between an input terminal and an output terminal are different in configuration.

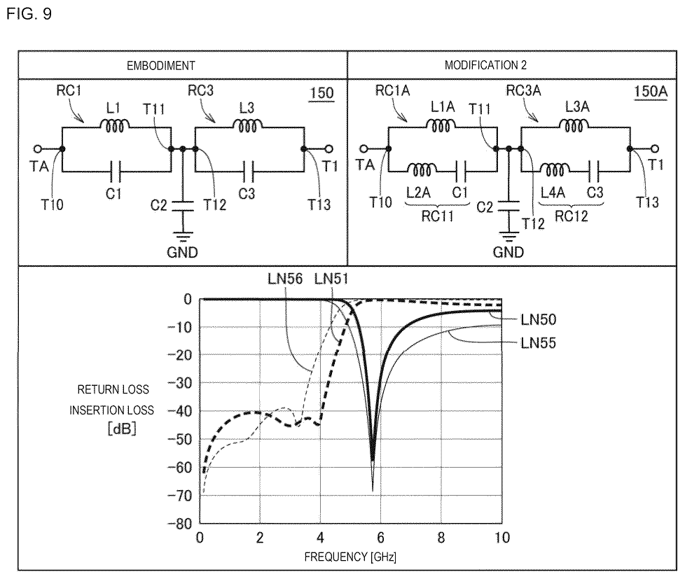

FIG. 9 includes diagrams illustrating a configuration and bandpass characteristics of a low pass filter in Modification 2. An upper section in FIG. 9 illustrates equivalent circuits of a third-order low pass filter 150 corresponding to the embodiment and a low pass filter 150A in Modification 2. A lower section in FIG. 9 illustrates bandpass characteristics (return loss, insertion loss) of the low pass filter 150 and the low pass filter 150A.

Note that, in each equivalent circuit, only a filter circuit portion is illustrated, and a coupling adjustment circuit is omitted. As the coupling adjustment circuit, a configuration, such as that of the adjustment circuit AC1 illustrated in FIG. 2, is used.

In the low pass filter 150, the resonator RC1 and the resonator RC3 are connected in series between the antenna terminal TA and the terminal T1. The resonator RC1 includes an inductor L1 and a capacitor C1 that are connected in parallel between a terminal T10 and a terminal T11. The resonator RC3 includes an inductor L3 and a capacitor C3 that are connected in parallel between a terminal T12 and a terminal T13. A capacitor C2 is connected between a connection node between the resonator RC1 and the resonator RC3 and the ground terminal GND.

On the other hand, in the low pass filter 150A, a resonator RC1A and a resonator RC3A are respectively disposed in place of the resonators RC1 and RC3 in the low pass filter 150. The resonator RCIA includes inductors L1A and L2A, and the capacitor C1. Furthermore, the resonator RC3A includes inductors L3A and L4A, and the capacitor C3.

In the resonator RCIA, the inductor LIA and a resonator RC11 including the inductor L2A and the capacitor C1 that are connected in series are connected in parallel between the terminal T10 and the terminal T11. Similarly, in the resonator RC3A, the inductor L3A and a resonator RC11 including the inductor L4A and the capacitor C3 that are connected in series are connected in parallel between the terminal T12 and the terminal T13.

A sum of the inductance values of the inductor LIA and the inductor L2A is the same as an inductance value of the inductor L1. A sum of the inductance values of the inductor L3A and the inductor L4A is the same as an inductance value of the inductor L3. For this reason, the resonant frequency of the resonator RCIA is the same as the resonant frequency of the resonator RC1. The resonant frequency of the resonator RC3A is the same as the resonant frequency of the resonator RC3. Hence, the frequency of an attenuation pole generated in the low pass filter 150A is the same as the frequency of an attenuation pole generated in the low pass filter 150.

However, the low pass filter 150A in Modification 2 is smaller in an inductance value in a signal transmission path from the antenna terminal TA to the terminal T1 (L1+L3>L1A+L3A). For this reason, loss that occurs in the signal transmission path in the low pass filter 150A is reduced compared with that in the low pass filter 150. Hence, such a resonator configuration as that in Modification 2 enables improved bandpass characteristics.

In the lower graph in FIG. 9, solid lines LN50 and LN51 respectively represent insertion loss and return loss in the low pass filter 150A in Modification 2. Furthermore, dashed lines LN55 and LN56 respectively represent insertion loss and return loss in the low pass filter 150 corresponding to the embodiment.

As illustrated in the graph in FIG. 9, in the low pass filter 150A, attenuation characteristics in the vicinity of the pass band in the non-pass band are steeper than those in the low pass filter 150. Note that, although attenuation at the attenuation pole is slightly reduced compared with that in the low pass filter 150, attenuation of about 60 dB is still achieved.

As described above, in each of the resonators connected in series in the signal transmission path from the input terminal to the output terminal, the inductor is split into inductors, and a first circuit constituted by an inductor of the inductors is connected in parallel with a second circuit constituted by a series resonant circuit including the other inductor and the capacitor, thereby making it possible to increase the steepness in attenuation characteristics.

In Modification 2, each of “inductor L1” and “inductor L3” corresponds to “first circuit” and “first coil” in the present disclosure. In Modification 2, each of “resonator RC11” and “resonator RC12” corresponds to “second circuit” in the present disclosure. In Modification 2, each of “terminal T10” and “terminal T12” corresponds to “first terminal” in the present disclosure. In Modification 2, each of “terminal T11” and “terminal T13” corresponds to “second terminal” in the present disclosure.

### Modification 3

In Modification 3, another example configuration of a resonator connected in series between the input terminal and the output terminal will be described.

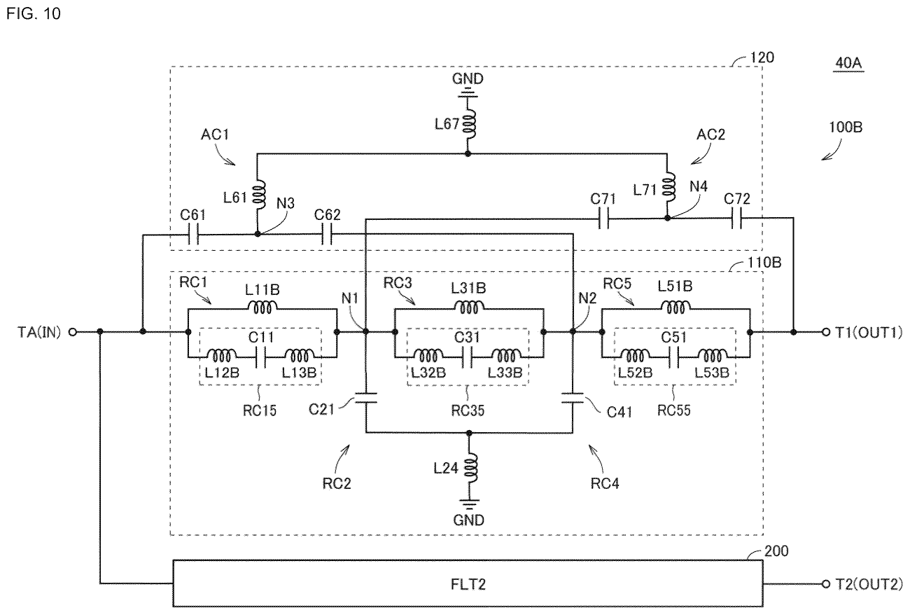

FIG. 10 is a diagram illustrating an example of an equivalent circuit of a diplexer 40A in which a low pass filter 100B according to Modification 3 is used. As in FIG. 2, in FIG. 10, only an equivalent circuit of the low pass filter 100B is illustrated, and an equivalent circuit of the high pass filter 200 is omitted.

Referring to FIG. 10, the low pass filter 100B includes a filter circuit 110B and the coupling adjustment circuit 120. In the filter circuit 110B, configurations of the resonators RC1, RC3, and RC5 differ from those in the low pass filter 100 illustrated in FIG. 2, and the other configurations are the same as those in the low pass filter 100. Note that the coupling adjustment circuit 120 is the same as that in the low pass filter 100 illustrated in FIG. 2.

As in Modification 2, the resonators RC1, RC3, and RC5 in the filter circuit 110B generally include one inductor and an LC series resonator that are connected in parallel.

The resonator RC1 includes an inductor L11B and a resonator RC15. The resonator RC15 includes inductors L12B and L13B, and the capacitor C11. In the resonator RC15, the capacitor C11 is connected between one end of the inductor L12B and one end of the inductor L13B. Furthermore, the other end of the inductor L12B is connected to one end of the inductor L11B and the antenna terminal TA. The other end of the inductor L13B is connected to the other end of the inductor L11B and the resonator RC3.

The resonator RC3 includes an inductor L31B and a resonator RC35. The resonator RC35 includes inductors L32B and L33B, and the capacitor C31. In the resonator RC35, the capacitor C31 is connected between one end of the inductor L32B and one end of the inductor L33B. Furthermore, the other end of the inductor L32B is connected to one end of the inductor L31B and the resonator RC1. The other end of the inductor L33B is connected to the other end of the inductor L31B and the resonator RC5.

The resonator RC5 includes an inductor L51B and a resonator RC55. The resonator RC55 includes inductors L52B and L53B, and the capacitor C51. In the resonator RC55, the capacitor C51 is connected between one end of the inductor L52B and one end of the inductor L53B. Furthermore, the other end of the inductor L52B is connected to one end of the inductor L51B and the resonator RC3. The other end of the inductor L53B is connected to the other end of the inductor L51B and the terminal T1.

Even in such a configuration, provision of the coupling adjustment circuit 120 enables improved attenuation characteristics in the non-pass band. Furthermore, in each of the resonators connected in series in the signal transmission path from the input terminal to the output terminal, the inductor is split into inductors, and a first circuit constituted by an inductor of the inductors is connected in parallel with a second circuit constituted by a series resonant circuit including the other inductor and the capacitor, thereby making it possible to increase the steepness in attenuation characteristics.

In Modification 3, each of “inductor L11B”, “inductor L31B”, and “inductor L51B” corresponds to “first circuit” and “first coil” in the present disclosure. In Modification 3, each of “resonator RC21”, “resonator RC31”, and “resonator RC41” corresponds to “second circuit” in the present disclosure.

The embodiment disclosed here is to be considered to be illustrative and not restrictive in any respect. The scope of the present invention is defined not by the above description of the embodiment, but by the claims, and is intended to include all changes made within the meaning and scope equivalent to the claims.

What is claimed is:

1. A low pass filter comprising:
a multilayer body including a plurality of dielectric layers stacked in a stacking direction;
an input terminal, an output terminal, and a ground terminal that are disposed at the multilayer body;
a first resonator connected to the input terminal, the first resonator being an LC parallel resonant circuit including a first inductor having a first primary inductor via extending in the stacking direction;
a second resonator connected between the first resonator and the output terminal, the second resonator being an LC parallel resonant circuit including a second inductor having a second primary inductor via extending in the stacking direction;
a first capacitor connected between a connection node between the first resonator and the second resonator and the ground terminal; and
a first adjustment circuit configured to adjust coupling between the first resonator and the second resonator,
wherein the first adjustment circuit includes a first adjustment circuit via having a first end connected to the ground terminal, and
wherein, in a plan view from the stacking direction, the first adjustment circuit via is between the first primary inductor via and the second primary inductor via.

2. The low pass filter according to claim 1,
wherein the first circuit via is capacitively coupled to the first primary inductor via and the second primary inductor via.

3. The low pass filter according to claim 1, comprising:
a third resonator connected between the second resonator and the output terminal, the third resonator being an LC parallel resonant circuit including a third inductor formed at least in part by a third primary inductor via extending in the stacking direction;
a second capacitor connected between a connection node between the second resonator and the third resonator and the ground terminal; and
a second adjustment circuit configured to adjust coupling between the second resonator and the third resonator,
wherein the second adjustment circuit includes a second adjustment circuit via having a first end connected to the ground terminal, and
wherein, in a plan view from the stacking direction, the second adjustment circuit via is disposed between the second primary inductor via and the third primary inductor via.

4. The low pass filter according to claim 3,
wherein the second adjustment circuit via is capacitively coupled to the second primary inductor via and the third primary inductor via.

5. The low pass filter according to claim 3, further comprising
a connection electrode configured to electrically connect the first adjustment circuit via and the second adjustment circuit via.

6. The low pass filter according to claim 5,
wherein the multilayer body includes a first main surface and a second main surface that are orthogonal to the stacking direction,
wherein the input terminal, the output terminal, and the ground terminal are disposed at the second main surface, and
wherein the connection electrode is disposed at a dielectric layer positioned closer to the first main surface than the dielectric layers where the first, second, and third primary inductor vias are primarily formed.

7. The low pass filter according to claim 3, further comprising
a ground inductor having a first end connected to the first capacitor and the second capacitor, and a second end connected to the ground terminal.

8. The low pass filter according to claim 3, further comprising
a stub connected to a second end of each of the first adjustment circuit via and the second end adjustment via.

9. The low pass filter according to claim 3, wherein the first adjustment circuit, the second adjustment circuit, the first capacitor, and the second capacitor share a common ground connection path to the ground terminal.

10. The low pass filter according to claim 3, wherein the connection electrode is configured to strengthen magnetic coupling between the first adjustment circuit and the second adjustment circuit to adjust magnetic field coupling between the first inductor and the third inductor.

11. The low pass filter according to claim 1, further comprising
a stub connected to a second end of the first adjustment circuit via.

12. The low pass filter according to claim 11, wherein the stub is an open stub configured to adjust a frequency of an attenuation pole.

13. The low pass filter according to claim 1,
wherein at least one of the first or second resonators includes
a first terminal and a second terminal, and
a first circuit and a second circuit connected in parallel with each other between the first terminal and the second terminal, and
wherein
the inductor of the at least one of the first or second resonators includes a first coil and a second coil,
the first circuit includes the first coil, and
the second circuit includes the capacitor and the second coil that are connected in series.

14. A diplexer comprising:
the low pass filter according to claim 1; and
a high pass filter connected to the input terminal.

15. The diplexer according to claim 14, wherein the input terminal is a common antenna terminal, the output terminal of the low pass filter is a first output terminal, and the high pass filter is connected between the common antenna terminal and a second output terminal.

16. A method of manufacturing a low pass filter, the method comprising:
forming a multilayer body by stacking a plurality of dielectric layers;
forming a first resonator connected to an input terminal, wherein forming the first resonator includes forming a first inductor having a first primary inductor via extending through at least a portion of the plurality of dielectric layers;
forming a second resonator connected between the first resonator and an output terminal, wherein forming the second resonator includes forming a second inductor having a second primary inductor via extending through at least a portion of the plurality of dielectric layers; and
forming a first adjustment circuit including an adjustment circuit via extending through at least a portion of the plurality of dielectric layers, the adjustment circuit via being connected to a ground terminal, wherein the adjustment circuit via is formed in a region between the first primary inductor via and the second primary inductor via.

17. The method of claim 16, further comprising forming a connection electrode on one of the plurality of dielectric layers to electrically connect the first adjustment circuit to a second adjustment circuit.

18. The method of claim 16, further comprising:
forming a third resonator connected between the second resonator and the output terminal, wherein forming the third resonator includes forming a third inductor having a third primary inductor via extending through at least a portion of the plurality of dielectric layers; and
forming a second adjustment circuit including a second adjustment circuit via extending through at least a portion of the plurality of dielectric layers, the second adjustment circuit via being connected to the ground terminal, wherein the second adjustment circuit via is formed in a region between the second primary inductor via and the third primary inductor via.

19. The method of claim 18, further comprising forming a connection electrode on one of the plurality of dielectric layers to electrically connect the adjustment circuit via of the first adjustment circuit to the second adjustment circuit via.
